(19) United States
(12) Patent Application Publication
(10) Pub. No.: US 2015/0145381 A1
(43) Pub. Date: May 28, 2015

(54) QUARTZ VIBRATOR AND MANUFACTURING METHOD THEREOF

(71) Applicant: SAMSUNG ELECTRO-MECHANICS CO., LTD., Gyeonggi-Do (KR)

(72) Inventor: Je Hong KYOUNG, Gyeonggi-Do (KR)

(73) Assignee: SAMSUNG ELECTRO-MECHANICS CO., LTD., Gyeonggi-Do (KR)

(21) Appl. No.: 14/190,501

(22) Filed: Feb. 26, 2014

(30) Foreign Application Priority Data
Nov. 26, 2013 (KR) 10-2013-0144670

(51) Int. Cl. H01L 41/047; H03H 9/13; H01L 41/29

(52) U.S. Cl. CPC H01L 41/047; H01L 41/29; H03H 9/13
USPC 310/365; 29/25.35

(57) ABSTRACT

Embodiments of the present invention provide a quartz vibrator and a method for manufacturing the same. The quartz vibrator includes a quartz substrate including an exciting part having a rectangular plate and a peripheral part having a thickness smaller than that of the exciting part and formed around the exciting part, a first electrode formed on one surface of the quartz substrate and the whole surface of the exciting part, and a second electrode formed on the other surface of the quartz substrate and the whole surface of the exciting part.

### CROSS REFERENCE TO RELATED APPLICATION

This application claims the benefit of and priority under 35 U.S.C. §119 to Korean Patent Application No. KR 10-2013-0144670, entitled, “Quartz Vibration and Manufacturing Method Thereof,” filed on Nov. 26, 2013, which is hereby incorporated by reference in its entirety into this application.

### BACKGROUND

1. Field of the Invention

The present invention relates to a quartz vibrator and a method for manufacturing the same.

2. Description of the Related Art

A quartz vibrator is generally used for several uses such as a frequency oscillator, a frequency regulator, a frequency converter, or the like.

The quartz vibrator uses quartz having excellent piezoelectric characteristics as a piezoelectric material, in which the quartz serves as a stable, mechanical vibration generator.

In this case, the quartz used as a piezoelectric material is artificially grown in a high pressure autoclave and is processed to have an appropriate size and shape by being cut based on its crystal axis so as to have desired characteristics, such that the quartz may be manufactured in a wafer form.

In this case, the quartz needs to be formed to have a low phase noise, a high quality (Q) value, and a low frequency change rate against a change in time and environment.

Here, the Q value indicates band selection characteristics in a resonator, a filter, an oscillator, and the like, and is called a quality factor. In addition, the Q value is calculated as a ratio of a central frequency to a 3 decibel (dB) bandwidth and the larger the Q value, the better the frequency selection characteristics of the oscillator becomes.

Such a quartz vibrator is completed by finely processing a quartz substrate three dimensionally by a micro electro mechanical system (MEMS), forming an upper electrode and a lower electrode, and mounting these electrodes in a ceramic package.

In this case, to tune a resonance frequency of the quartz vibrator to a range of an available frequency prior to completing a final package, a frequency trimming process is performed.

According to conventional quartz vibrators as described above, a pattern of a protruding portion of the quartz substrate has a rectangular shape or a circular shape and has a structure independently spaced apart from the electrodes on the quartz substrate, such that the pattern is formed to be different from an electrode pattern in a structure and a shape.

As a result, since the protruding portion of the quartz substrate is different from the electrode structure, it is difficult to implement alignment when the electrode pattern is formed at the protruding portion of the quartz substrate to cause an alignment error, such that center mis-matching may occur.

Further, according to the conventional quartz vibrators as described above, a frequency trimming method, which is a method of determining an electrode etching region of an ion beam through a shadow mask, cannot help increasing a trimmed area due to a tolerance of the shadow mask manufactured by mechanical processing and the alignment error of the quartz vibrator and the shadow mask.

Therefore, since it is impossible to implement the trimming at an accurate position, it is difficult to perform a precise control of a frequency, the frequency scattering is large, and in severe cases, a disconnection defect of the electrode occurs to make it difficult to manage the trimming.

### SUMMARY

Embodiments of the present invention have been made in an effort to provide a quartz vibrator and a method for manufacturing the same capable of prevent mis-matching from occurring during a manufacturing process by making a shape of a protruding portion of a quartz substrate be the same shape as an electrode pattern.

Further, embodiments of the present invention have been made in an effort to provide a quartz vibrator and a method for manufacturing the same capable of performing a trimming process on only a desired portion at the time of performing the trimming by forming an electrode protective layer.

According to an embodiment of the present invention, there is provided a quartz vibrator, including a quartz substrate including an exciting part having a rectangular plate and a peripheral part having a thickness smaller than that of the exciting part and formed around the exciting part, a first electrode formed on one surface of the quartz substrate and the whole surface of the exciting part, and a second electrode formed on the other surface of the quartz substrate and the whole surface of the exciting part.

In accordance with an embodiment of the present invention, the quartz vibrator further includes a first protective layer including an opening corresponding to a trimming region of the first electrode and formed on the first electrode.

In accordance with an embodiment of the present invention, the quartz vibrator further includes a first pad formed on one surface of the quartz substrate, and a first drawing electrode connecting the first pad to the first electrode. The exciting part protrudes in a shape corresponding to the first pad and the first drawing electrode and the first pad and the first drawing electrode are formed at the corresponding shape portion of the exciting part.

In accordance with an embodiment of the present invention, the exciting part formed with the first pad, the first drawing electrode, and the first electrode are a flat plane.

In accordance with an embodiment of the present invention, the quartz vibrator further includes a first protective layer including an opening corresponding to a trimming region of the first electrode, formed on the first electrode, formed to include an opening corresponding to a connection portion formed on the first pad, and formed on a surface of the first drawing electrode.

In accordance with an embodiment of the present invention, the first protective layer is formed on the first electrode and the first pad and a surface and a side of the first drawing electrode.

In accordance with an embodiment of the present invention, the quartz vibrator further includes a second pad formed on the other surface of the quartz substrate, and a second drawing electrode connecting the second pad to the second electrode. The exciting part protrudes in a shape corresponding to the second pad and the second drawing electrode and the second pad and the second drawing electrode are formed at the corresponding shape portion of the exciting part.

In accordance with an embodiment of the present invention, the second protective layer is formed on the second electrode and the second pad and a surface and a side of the second drawing electrode.

In accordance with an embodiment of the present invention, the exciting part formed with the second pad, the second drawing electrode, and the second electrode are a flat plane.

In accordance with an embodiment of the present invention, the quartz vibrator further includes a second protective layer including an opening corresponding to a trimming region of the second electrode, formed on the second electrode, formed to include an opening corresponding to a connection portion formed on the second pad, and formed on a surface of the second drawing electrode.

In accordance with an embodiment of the present invention, the first electrode is provided with a depressed part corresponding to the opening of the first protective layer.

In accordance with an embodiment of the present invention, the first protective layer is made of any one selected from a group consisting of aluminum oxide (Al₂O₃), aluminum nitride (AlN), aluminum oxynitride (AlON), silicon oxide (SiOx), silicon nitride (SiNx), silicon oxynitride (SiOxNy), silicon carbide (SiC), and titanium oxide (TiOx).

According to another embodiment of the present invention, there is provided a method for manufacturing a quartz vibrator, including (A) forming a plurality of first and second electrodes on both surfaces of a reserved quartz substrate, (B) dividing the reserved quartz substrate into the quartz substrate including one first electrode and second electrode by using a metal mask, and (C) forming an exciting part protruding from a peripheral part of the quartz substrate and the first and second electrodes having the same shape as the exciting part by half-etching the first and second electrodes and the quartz substrate using a metal mask.

In accordance with an embodiment of the present invention, step (A) includes step (A-1) forming a first metal layer and a second metal layer on both surfaces of a reserved quartz substrate, step (A-2) forming a first resist layer on the first metal layer and forming a second resist layer on the second metal layer, step (A-3) patterning the first resist layer and the second resist layer as an electrode pattern, and step (A-4) forming the first and second electrodes by etching the first metal layer and the second metal layer using the first resist layer and the second resist layer.

In accordance with an embodiment of the present invention, step (B) includes step (B-1) forming a first metal mask on the first electrode of the quartz substrate and a second metal mask on the second electrode, and step (B-2) dividing the reserved quartz substrate into the quartz substrate including one first and second electrode by using the first and second metal masks and the first and second electrodes.

In accordance with an embodiment of the present invention, step (C) includes step (C-1) half-etching the first and second electrodes and the quartz substrate by using the first and second metal masks, step (C-2) forming the exciting part protruding from the peripheral part of the quartz substrate and the first and second electrodes having the same shape as the exciting part, and step (C-3) removing the first and second metal masks.

In accordance with an embodiment of the present invention, in step (C), one surface of the quartz substrate is provided with a first pad and a first drawing electrode connecting the first pad to the first electrode and the exciting part is formed to protrude in a shape corresponding to the first pad and the first drawing electrode.

In accordance with an embodiment of the present invention, in step (C), the other surface of the quartz substrate is provided with a second pad and a second drawing electrode connecting the second pad to the second electrode and the exciting part is formed to protrude in a shape corresponding to the second pad and the second drawing electrode.

In accordance with an embodiment of the present invention, the method for manufacturing a quartz vibrator further includes: after step (A), step (D) forming a first protective layer to enclose the first electrode and forming a second protective layer to enclose the second electrode, and after step (C), step (E) exposing a trimming region of the first electrode by removing a central portion of the first protective layer and exposing a trimming region of the second electrode by removing a central portion of the second protective layer.

In accordance with an embodiment of the present invention, step (D) includes step (D-1) stacking a first insulating layer on the first electrode and stacking a second insulating layer on the second electrode, and step (D-2) forming the first protective layer to enclose the first electrode by patterning the first insulating layer and forming the second protective layer to enclose the second electrode by patterning the second insulating layer.

In accordance with an embodiment of the present invention, in step (A), the first pad and the first drawing electrode connecting the first pad to the first electrode are further formed and in step (D), the first protective layer is formed on the first drawing electrode.

In accordance with an embodiment of the present invention, in step (A), the second pad and the second drawing electrode connecting the second pad to the second electrode are further formed and in the step (D), the second protective layer is formed on the second drawing electrode.

Various objects, advantages and features of the present invention will become apparent from the following description of embodiments with reference to the accompanying drawings.

### BRIEF DESCRIPTION OF DRAWINGS

These and other features, aspects, and advantages of the present invention are better understood with regard to the following Detailed Description, appended Claims, and accompanying Figures. It is to be noted, however, that the Figures illustrate only various embodiments of the present invention and are therefore not to be considered limiting of the invention's scope as it may include other effective embodiments as well.

FIG. 1 is a front plan view schematically illustrating a quartz vibrator according to an embodiment of the present invention.

FIG. 2 is a rear plan view schematically illustrating the quartz vibrator according to an embodiment of the present invention.

FIG. 3 is a cross-sectional view taken along the line A-A′ of FIG. 1 schematically illustrating the quartz vibrator according to an embodiment of the present invention.

FIG. 4 is a cross-sectional view taken along the line B-B′ of FIG. 1 schematically illustrating the quartz vibrator according to an embodiment of the present invention.

FIG. 5 is a perspective view of the quartz vibrator according to an embodiment of the present invention.

FIG. 6 is a perspective view schematically illustrating an AT cut quartz substrate according to an embodiment of the present invention.

FIG. 7 is a front plan view schematically illustrating a quartz vibrator according to an embodiment of the present invention.

FIG. 8 is a rear plan view schematically illustrating the quartz vibrator according to an embodiment of the present invention.

FIG. 9 is a cross-sectional view taken along the line A-A′ of FIG. 7 schematically illustrating the quartz vibrator according to an embodiment of the present invention.

FIG. 10 is a cross-sectional view taken along the line B-B′ of FIG. 8 schematically illustrating the quartz vibrator according to an embodiment of the present invention.

FIG. 11 is a cross-sectional view of a final product according to an embodiment of the present invention.

FIGS. 12 to 18 are diagrams schematically illustrating a process of manufacturing a quartz vibrator 100 according to an embodiment of the present invention.

FIGS. 19 to 32 are diagrams schematically illustrating the process of manufacturing a quartz vibrator according to an embodiment of the present invention.

### DETAILED DESCRIPTION

The present invention will now be described more fully hereinafter with reference to the accompanying drawings, which illustrate embodiments of the present invention. This invention may, however, be embodied in many different forms and should not be construed as limited to the illustrated embodiments set forth herein. Rather, these embodiments are provided so that this disclosure will be thorough and complete, and will fully convey the scope of the present invention to those skilled in the art. Like numbers refer to like elements throughout. Prime notation, if used, indicates similar elements in alternative embodiments.

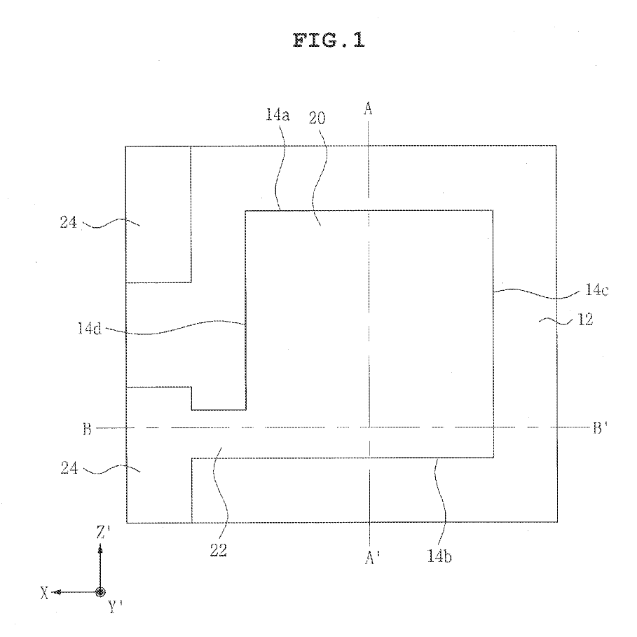

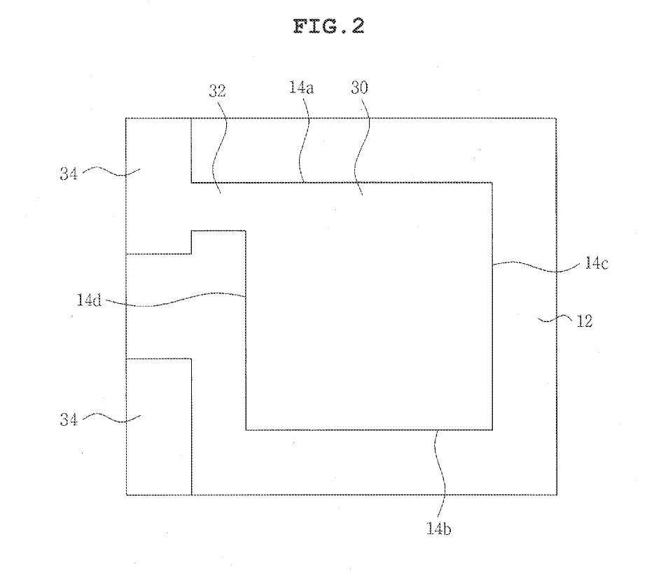

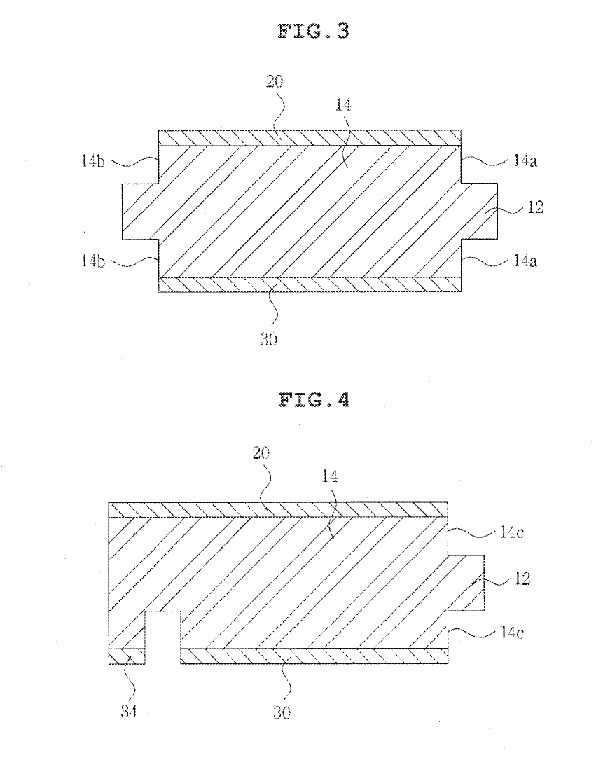

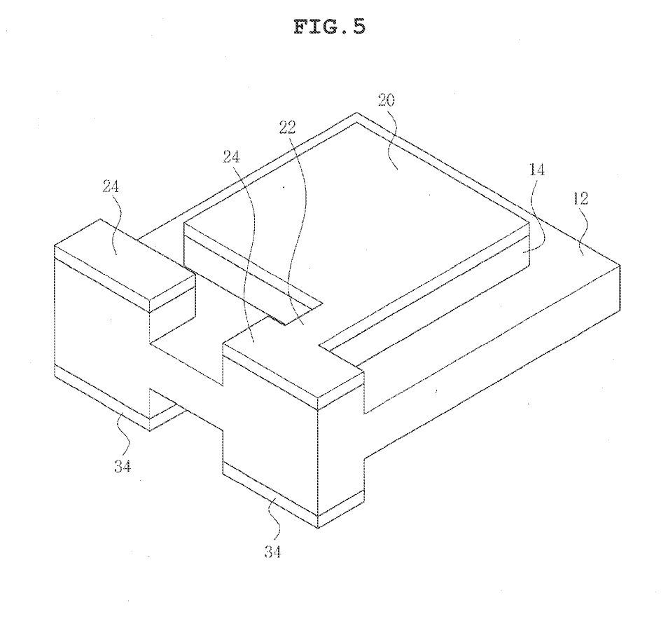

FIG. 1 is a front plan view schematically illustrating a quartz vibrator according to an embodiment of the present invention, FIG. 2 is a rear plan view schematically illustrating the quartz vibrator according to an embodiment of the present invention, FIG. 3 is a cross-sectional view taken along the line A-A′ of FIG. 1 schematically illustrating the quartz vibrator according to an embodiment of the present invention, FIG. 4 is a cross-sectional view taken along the line B-B′ of FIG. 1 schematically illustrating the quartz vibrator according to an embodiment of the present invention, and FIG. 5 is a perspective view of the quartz vibrator according to an embodiment of the present invention.

Referring to FIGS. 1 to 5, the quartz vibrator according to an embodiment of the present invention includes a quartz substrate 10, an upper electrode 20, and a lower electrode 30.

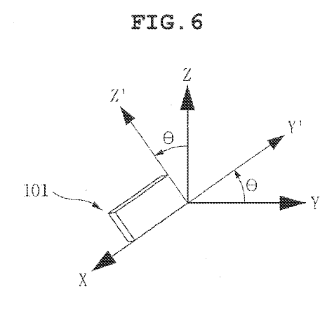

In accordance with an embodiment of the present invention, the quartz substrate 10 is configured of an AT cut quartz substrate. FIG. 6 is a perspective view schematically illustrating an AT cut quartz substrate 101 according to an embodiment of the present invention.

A piezoelectric material such as quartz is generally a trigonal system and has crystal axes X, Y, and Z illustrated in FIG. 6. The X axis is an electrical axis, the Y axis is a mechanical axis, and a Z axis is an optical axis.

In accordance with an embodiment of the present invention, the AT cut quartz substrate 101 is a flat plate cut from a piezoelectric material (for example, synthetic quartz) along a plane at which an XZ plane rotates by the angle θ at an X-axis circumference.

In at least one embodiment, θ=35° 15′. Further, the Y axis and the Z axis rotates by θ at the X-axis circumference, and thus each are a Y′ axis and a Z′ axis.

Therefore, the AT cut quartz substrate 101 has crystal axes X, Y′ and Z′. The AT cut quartz substrate 101 in which an XZ′ surface (surface including the X axis and the Z′ axis) orthogonal to the Y′ axis is a main surface (exciting surface) is vibrated by using a thickness shearing vibration as a main vibration. The AT cut quartz substrate 101 is processed to be able to obtain the quartz substrate 10.

In accordance with an embodiment of the present invention, the quartz substrate 10 has a rectangular shape in which as illustrated in FIGS. 1 and 2, a direction (referred to as ‘X-axis direction’) parallel with the X axis by setting a direction (hereinafter, referred to as ‘Y′-axis direction’) parallel with the Y′ axis as a thickness direction is a long side and a direction (hereinafter, referred to as ‘Z′-axis direction’) parallel with the Z′ axis is a short side. The quartz substrate 10 has a peripheral part 12 and an exciting part 14.

As illustrated in FIGS. 1 and 2, the peripheral part 12 is formed around the exciting part 14. The peripheral part 12 has a thickness smaller than that of the exciting part 14.

As illustrated in FIGS. 1 and 2, the exciting part 14 is enclosed with the peripheral part 12 and has a thickness larger than that of the peripheral part 12 in the Y′-axis direction.

As illustrated in FIGS. 3 and 4, the exciting part 14 protrudes in the Y′-axis direction with respect to the peripheral part 12.

In the illustrated example, the exciting part 14 protrudes to a+Y′ side and a−Y′ side with respect to the peripheral part 12. The exciting part 14 (quartz substrate 10) has, for example, a point (not illustrated) which is a symmetrical center and may have a point symmetry shape.

As illustrated in FIGS. 1 and 2, the exciting part 14 has a rectangular shape in which the X-axis direction is a long side and the Z′-axis direction is a short side.

In the exciting part 14, a side parallel with the X axis is a long side and a side parallel with the Z′ axis is a short side.

For this reason, the exciting part 14 has sides 14a and 14b extending in the X-axis direction and sides 14c and 14d extending in the Z′-axis direction. A length direction of the sides 14a and 14b extending in the X-axis direction is the X-axis direction and a length direction of the sides 14c and 14d extending in the Z′-axis direction is the Z′ axis direction.

For example, as illustrated in FIGS. 1 and 2, the side 14a extending in the X-axis direction is formed at a +Y′ axis and −Y′ side with respect to the peripheral part 12. The same is true for the sides 14b, 14c, and 14d.

As illustrated in FIGS. 1 and 2, each of the sides 14a and 14b extending in the X-axis direction is within one plane. The side 14a of the +Y′ side is within one plane and the side 14a of the −Y′ side is within one plane. Similarly, the side 14b of the +Y′ side is within one plane and the side 14b of the −Y′ side is within one plane.

Further, in accordance with at least one embodiment of the present invention, the ‘within one plane’ includes a case in which a side of the exciting part 14 is a flat surface and a case in which the side of the exciting part 14 has ruggedness as much as crystal anisotropy of quartz. That is, when the AT cut quartz substrate is processed by using a solution including hydrofluoric acid as an etching solution, there may be the case in which the side of the exciting part 14 is a surface parallel with an XY′ surface due to the exposure of an R surface of the quartz crystal and the case in which the side of the exciting part 14 has ruggedness as much as the crystal anisotropy of quartz due to the exposure of an m surface of the quartz crystal. In accordance with at least one embodiment of the present invention, even the side having the ruggedness due to the m surface of the quartz crystal is believed to be the ‘within one plane’. For convenience, FIGS. 1 and 2 do not illustrate the ruggedness due to the m surface. Further, the AT cut quartz substrate is processed by a laser, such that only the R surface of the quartz crystal is exposed.

In accordance with an embodiment of the present invention, the exciting part 14 is vibrated by using the thickness shearing vibration as the main vibration.

In particular, the exciting part 14 protrudes to the +Y′ side with respect to the peripheral part 12 in the same shape as the upper electrode 20 formed thereon.

Further, the exciting part 14 protrudes to the −Y′ side from the peripheral part 12 in the same shape as the lower electrode 20 formed therebeneath.

In addition, the exciting part 14 protrudes to the +Y′ side with respect to the peripheral part 12 in the same shape as an upper drawing electrode 22 formed thereon.

Further, the exciting part 14 protrudes to the −Y′ side with respect to the peripheral part 12 in the same shape as a lower drawing electrode 32 formed therebeneath.

In addition, the exciting part 14 protrudes to the +Y′ side with respect to the peripheral part 12 in the same shape as the upper pad 24 formed thereon.

Further, the exciting part 14 protrudes to the −Y′ side with respect to the peripheral part 12 in the same shape as a lower pad 34 formed therebeneath.

This is clear from FIG. 5 which is a perspective view and the exciting part 14 protrudes to the +Y side with respect to the peripheral part 12 in the same shape as a shape indicated when the upper electrode 20—upper drawing electrode 22—upper pad 24 are projected down.

Further, the exciting part 14 protrudes to the −Y′ side with respect to the peripheral part 12 in the same shape as a shape indicated when the lower electrode 30—lower drawing electrode 32—lower pad 34 are projected up.

Meanwhile, the upper electrode 20 is formed on the exciting part 14 and the lower electrode 30 is formed beneath the exciting part 14. In the example illustrated in FIGS. 3 and 4, the upper electrode 20 and the lower electrode 30 are formed, having the exciting part 14 formed therebetween.

In more detail, the upper electrode 20 and the lower electrode 30 are disposed to face each other at the front and rear of the vibration region (exciting part 14) of both main surfaces (for example, a surface parallel with the XZ′ plane) of the substrate 10. The upper electrode 20 and the lower electrode 30 may apply a voltage to the exciting part 14.

The upper electrode 20 is connected to the upper pad 24 through, for example, the upper drawing electrode 22. Further, the lower electrode 30 is connected to the lower pad 34 through, for example, the lower drawing electrode 32.

Herein, the upper drawing electrode 22 does not have a step unlike the prior art since the exciting part 14 protrudes from the peripheral part 12 in the same shape.

Further, in accordance with an embodiment of the present invention, the lower drawing electrode 32 does not also have a step unlike the prior art since the exciting part 14 protrudes from the peripheral part 12 in the same shape.

The upper pad 24 and the lower pad 34 are electrically connected to, for example, an IC chip (not illustrated) to drive a quartz vibrator 100.

The upper electrode 20, the upper drawing electrode 22, the upper pad 24, the lower electrode 30, the lower drawing electrode 32, and the lower pad 34 may use, for example, one in which chromium and gold are stacked in order from the substrate 10 side.

According to an embodiment of the present invention as described above, the exciting part 14 protrudes from the peripheral part 12 in the same shape as the upper electrode—upper drawing electrode—upper pad or the lower electrode—lower drawing electrode —lower pad and thus may have the following advantages.

1) Since the protruding portion of the quartz substrate is different from the electrode structure, the manufacturing method according to the prior art needs to further perform the separate electrode pattern process after the pattern of the protruding portion of the quartz substrate is completed, but according to the embodiment of the present invention, since the protruding structure of the quartz substrate is the same as the electrode structure, the metal mask for forming the protruding structure of the quartz substrate may be used as the electrode as it is, and therefore there is no need to perform the separate electrode pattern process.

2) Further, according to the structure of the conventional art, the protruding portion and the electrode structure are formed with the electrode pattern through the step and thus it is highly likely to increase the disconnection risk at the time of forming the electrode in terms of the section characteristic, while according to the structure of various embodiments of the present invention, since the protruding structure is the same as the electrode, there is no risk of the electrode disconnection.

3) Further, according to an embodiment of the present invention, since the protruding portion of the quartz substrate is the same as the electrode structure, after the protruding portion of the quartz substrate is patterned, the metal mask is used as the electrode as it is, such that there is no need to perform the separate electrode pattern process. As a result, the manufacturing costs may be reduced by simplifying the process and reducing the frequency of the process of using gold which is a precious metal.

4) In addition, according to an embodiment of the present invention, it is possible to prevent the center mis-mismatching from occurring during the manufacturing process by making the shape of the protruding portion of the quartz substrate be the same as that of the electrode pattern.

5) Further, according to an embodiment of the present invention, since the protruding portion of the quartz vibrator and the electrode pattern have the same structure, it is possible to maximize the electrode area formed at the protruding portion of the quartz substrate and it is possible to secure the ESR improvement effect by increasing the electrode area.

6) Further, in the case of the structure according to the conventional art, since the appearance of the quartz substrate is formed and then the electrode pattern process is performed, the electrode process is performed in the state in which it is structurally very vulnerable to the impact, thereby causing the problem of the chip loss, the substrate damage, and the like, while according to an embodiment of the present invention, after the appearance of the quartz substrate is formed, there is a need to perform the separate electrode process, thereby minimizing the substrate damage, the chip loss, and the like.

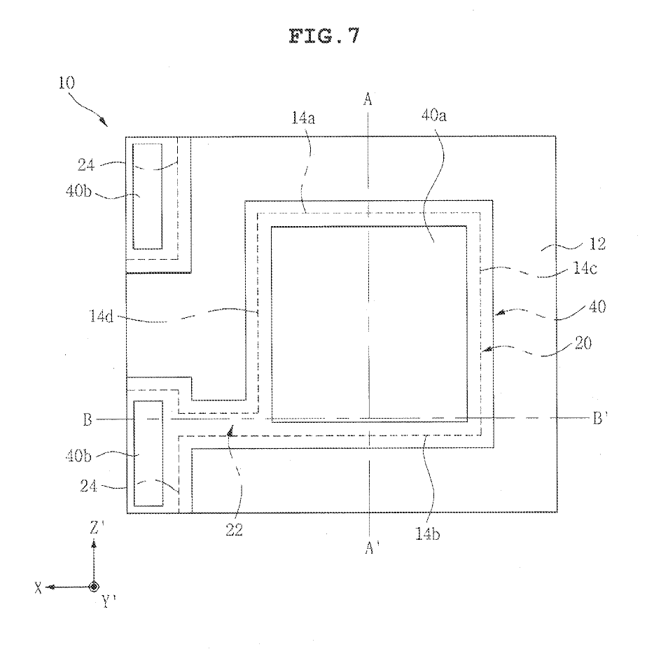

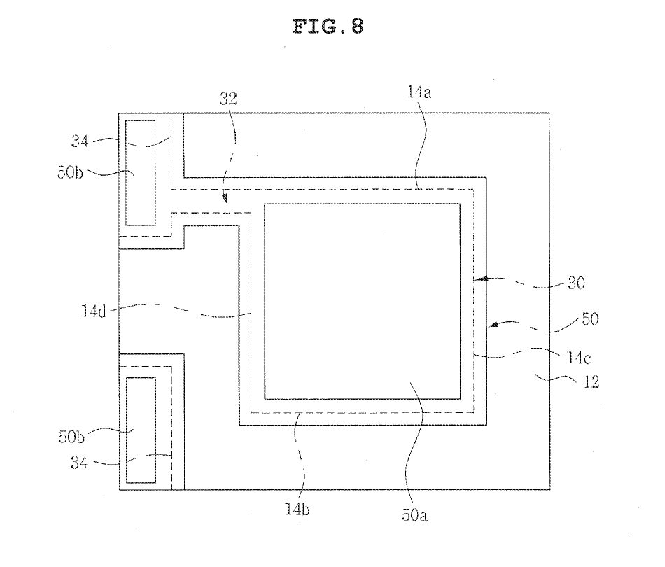

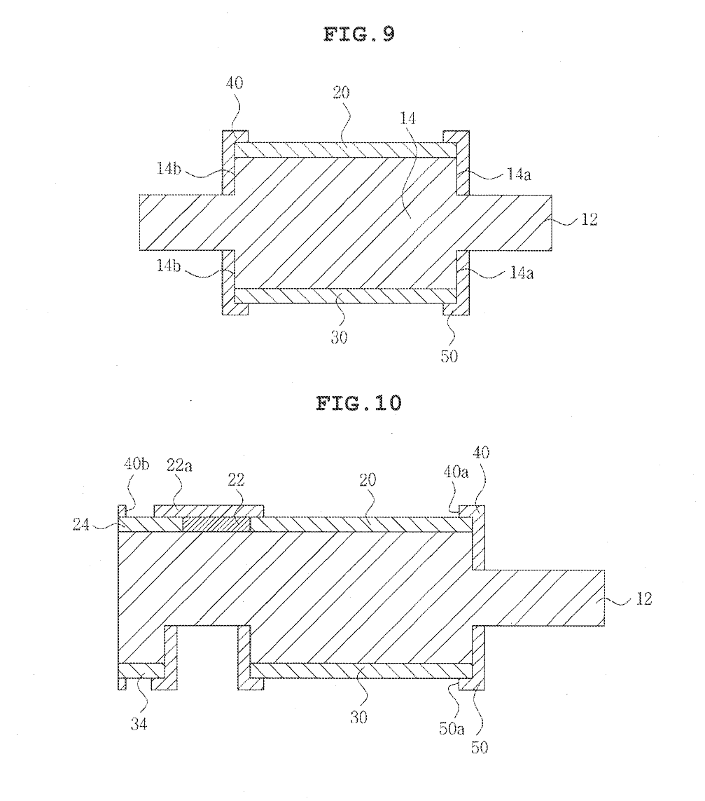

FIG. 7 is a front plan view schematically illustrating a quartz vibrator according to an embodiment of the present invention, FIG. 8 is a rear plan view schematically illustrating the quartz vibrator according to an embodiment of the present invention, FIG. 9 is a cross-sectional view taken along the line A-A′ of FIG. 7 schematically illustrating the quartz vibrator according to an embodiment of the present invention, and FIG. 10 is a cross-sectional view taken along the line B-B′ of FIG. 8 schematically illustrating the quartz vibrator according to an embodiment of the present invention.

A quartz vibrator according to an embodiment of the present invention is different from the quartz vibrator according to the embodiment of the present invention illustrated in FIGS. 1 to 6 in that the quartz vibrator further includes an upper protective layer 40 and a lower protective layer 50, but other components are the same as those of the quartz vibrator according to the embodiment of the present invention illustrated in FIGS. 1 to 6.

Therefore, only the upper protective layer 40 and the lower protective layer 50 will be described below and other components are the same as the above description and therefore the description thereof will be omitted.

In accordance with an embodiment of the present invention, the upper protective layer 40 is formed on the upper portion and side of the upper electrode 20 and the side of the exciting part 14 and the lower protective layer 50 is formed on the lower portion and side of the lower electrode 30 and the side of the exciting part 14.

A central portion of the upper protective layer 40 is provided with an opening 40a to open the trimming region of the upper electrode 20.

The upper protective layer 40 is formed to contact the upper portion and side of the upper electrode 20, but may be formed on only the upper portion of the upper electrode 20.

Further, in accordance with an embodiment of the present invention, the upper protective layer 40 is formed at the exposed portion of the upper drawing electrode 22 to protect the upper drawing electrode 22, so that the upper drawing electrode 22 is not etched at the time of performing the trimming process.

Further, the upper protective layer 40 is formed by disposing an opening 40b at the upper pad 24 and protects the upper pad 24, so that a front surface of the upper pad 24 is not etched at the time of the trimming and is connected to an external terminal.

Further, a central portion of the lower protective layer 50 is provided with an opening 50a to open the trimming region of the lower electrode 30.

Such a lower protective layer 50 is formed to contact the lower portion and side of the lower electrode 30, but may be formed on only the lower portion of the lower electrode 20.

Further, in accordance with an embodiment of the present invention, the lower protective layer 50 is formed at an exposed portion of the lower drawing electrode 32 to protect the lower drawing electrode 32, so that the lower drawing electrode 32 is not etched at the time of performing the trimming process.

Further, the lower protective layer 50 is formed by disposing an opening 50b at the lower pad 34 and protects the lower pad 34, so that a front surface of the lower pad 34 is not etched at the time of the trimming and may be connected to the external terminal.

In accordance with an embodiment of the present invention, the upper protective layer 40 and the lower protective layer 50 are formed, having the exciting part 14 and the upper electrode 20 and the lower electrode 30 disposed therebetween.

In more detail, the upper protective layer 40 and the lower protective layer 50 are disposed to face each other at the front and rear of the vibration region (exciting part 14) of both main surfaces (for example, a surface parallel with the XZ′ plane) of the substrate 10. As such, as the upper protective layer 40 and the lower protective layer 50 are formed to be symmetrical with each other, it is possible to control the frequency by selectively etching the lower electrode 30 in addition to controlling the frequency by etching the upper electrode 20 at the time of performing the trimming process.

In addition, the upper protective layer 40 and the lower protective layer 50 serve to protect elements from external mechanical impact, moisture, radioactive particles, and the like.

In accordance with an embodiment of the present invention, the upper protective layer 40 and the lower protective layer 50 is a nitride layer or an oxide layer. The upper protective layer 40 and the lower protective layer 50 are made of one selected from the group consisting of aluminum oxide (Al₂O₃), aluminum nitride (AlN), aluminum oxynitride (AlON), silicon oxide (SiOx), silicon nitride (SiNx), silicon oxynitride (SiOxNy), silicon carbide (SiC), titanium oxide (TiOx), and the like.

According to an embodiment of the present invention, the trimming process is performed by using the upper protective layer 40 or the lower protective layer 50. In this case, the upper electrode 20 or the lower electrode 30, which is etched, has a depressed part 60, as illustrated in FIG. 11. The depressed part 60 is reflected to a final product of the quartz vibrator 10.

According to another embodiment of the present invention as described above, the following effects may be obtained, in addition to the effects according to the embodiment of the present invention, as described above.

First, the upper protective layer 40 or the lower protective layer 50 serves as the existing shadow mask at the time of performing the trimming process to be able to radically remove the trimming region error occurring due to the mechanical processing such as the application of the existing shadow mask. Therefore, it is possible to very precisely control the trimming region.

Further, according to an embodiment of the present invention, at the time of performing the frequency trimming of the quartz vibrator, only the electrode region previously patterned is trimmed, such that the frequency may be easily controlled and the frequency scattering may be kept to be small.

Further, at the time of performing the trimming by the existing method, the defect of the drawing electrode occurs due to the step between the exciting part and the peripheral part while the trimming process is performed, but by using the improved method, it is little likely to cause the defect of the drawing electrode.

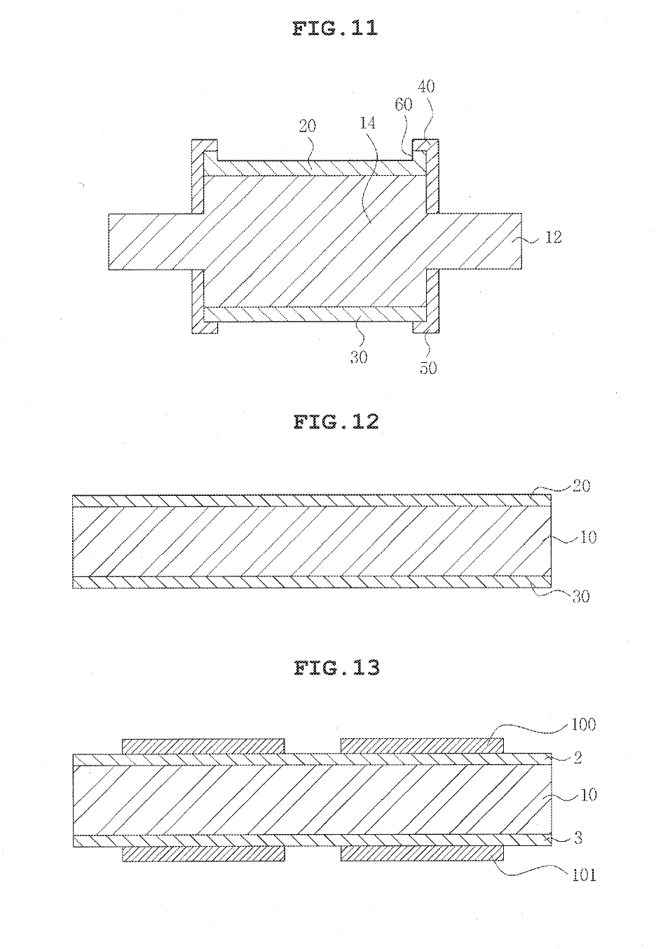

Next, the method for manufacturing a quartz vibrator according to an embodiment of the present invention will be described with reference to the drawings. FIGS. 12 to 18 are diagrams schematically illustrating a process of manufacturing a quartz vibrator 100 according to an embodiment of the present invention.

As illustrated in FIG. 12, a double-side main surface (surface parallel with the XZ′ plane) of the quartz substrate 10 is provided with the upper metal layer 2 and the lower metal layer 3. The upper metal layer 2 and the lower metal layer 3 are formed by stacking chromium and gold in order by a spatter method, a vacuum deposition method, and the like.

As illustrated in FIG. 13, an upper resist layer 100 and a lower resist layer 101 having a predetermined shape are formed by applying a positive type photoresist layer on both surfaces and then exposing and developing the photoresist layer. The resist layers 100 and 101 are formed to cover a remaining portion of the upper metal layer 2 and the lower metal layer 3 in the following process.

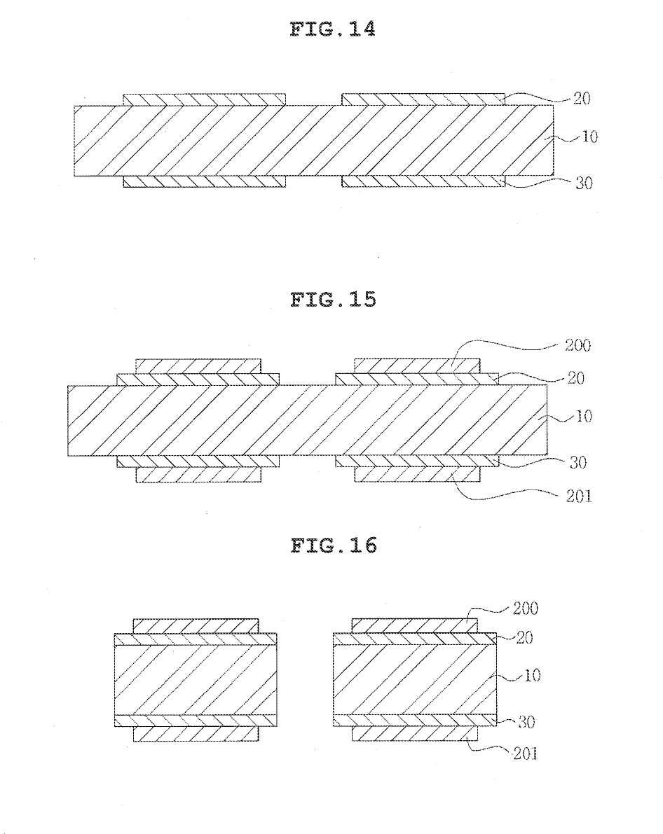

As illustrated in FIG. 14, the upper electrode 20 and the lower electrode 30 are formed by etching the upper metal layer 2 and the lower metal layer 3 depending on the patterns formed on the resist layers 100 and 101.

Further, as illustrated in FIG. 15, the upper metal mask 200 made of Cr/Au, and the like is formed on the upper electrode 20 and a lower metal mask 201 is stacked on the lower electrode 30 and then patterned, such that they have the same shape as the exciting part 14. The patterning is performed by, for example, a photolithography technology and an etching technology.

Next, as illustrated in FIG. 16, the quartz substrate 10 is etched by using the metal masks 200 and 201 and the upper electrode 20 and the lower electrode 30. The etching is performed by using, for example, a mixing solution of hydrofluoric acid and ammonium fluoride as an etching solution. By doing so, an appearance (shape when viewed in the Y′-axis direction) of the quartz substrate 10 is formed.

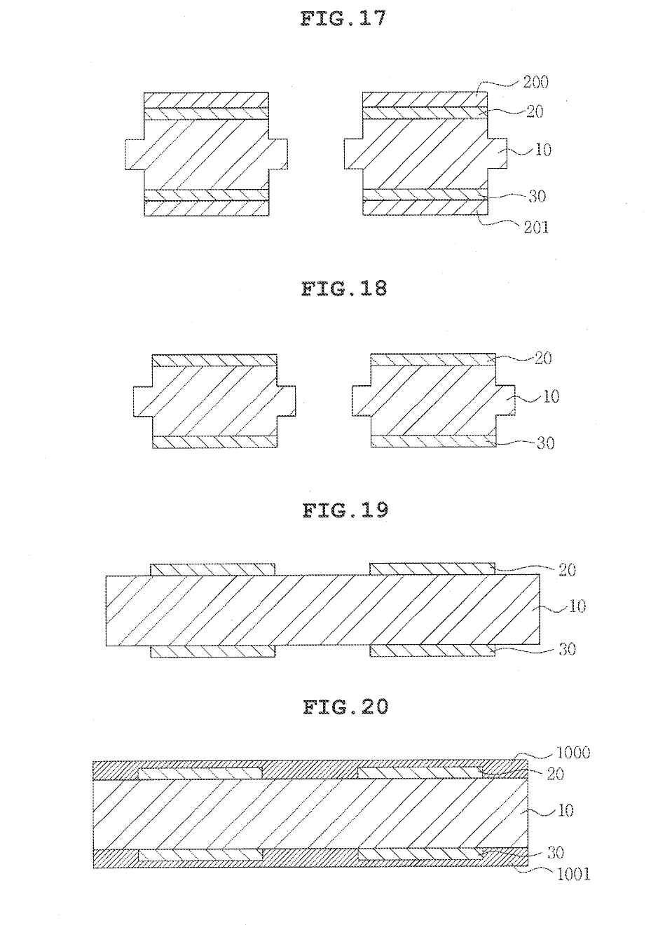

Next, as illustrated in FIG. 17, the AT cut quartz substrate 10 is half-etched up to a predetermined depth with a predetermined etching solution by using the metal masks 200 and 201. By doing so, the appearance of the exciting part 14 and the final shape of the upper electrode 20 and the lower electrode 30 are formed.

As illustrated in FIG. 18, the metal mask M is developed and removed.

According to the process in accordance with an embodiment of the present invention, when the appearance of the exciting part 14 is formed, since the appearance of the exciting part 14 is the same as that of the upper electrode 20 and the lower electrode 30 finally formed, the etching is performed by using the metal masks 200 and 201 without forming the separate resist layer, thereby simplifying the process. Further, as the process is simplified, yield is improved, process costs are saved, and production time is shortened.

Next, a method for manufacturing a quartz vibrator according to another embodiment of the present invention will be described with reference to the drawings.

FIGS. 19 to 32 are diagrams schematically illustrating a process of manufacturing a quartz vibrator according to another embodiment of the present invention.

First, as illustrated in FIG. 19, the double-side main surface (surface parallel with the XZ′ plane) of the quartz substrate 10 is provided with the upper electrode 20 and the lower electrode 30. The upper electrode 20 and the lower electrode 30 are formed by stacking chromium and gold on the upper metal layer and the lower metal layer in order by the spatter method, the vacuum deposition method, or the like and then patterning the upper metal layer and the lower metal layer. The patterning is performed by, for example, the photolithography technology and the etching technology.

Further, as illustrated in FIG. 20, an upper insulating layer 1000 and a lower insulating layer 1001 are formed on both surfaces of the quartz substrate 10 on which the upper electrode 20 and the lower electrode 30 are formed.

In accordance with an embodiment of the present invention, the upper insulating layer 1000 and the lower insulating layer 1001 are a nitride layer or an oxide layer and are formed by the spatter method, the vacuum deposition method, and the like. The upper insulating layer 1000 and the lower insulating layer 1001 are made of one selected from the group consisting of aluminum oxide (Al₂O₃), aluminum nitride (AlN), aluminum oxynitride (AlON), silicon oxide (SiOx), silicon nitride (SiNx), silicon oxynitride (SiOxNy), silicon carbide (SiC), titanium oxide (TiOx), and the like.

Next, as illustrated in FIG. 21, an upper resist layer 2000 and a lower resist layer 2001 having a predetermined shape are formed by applying a positive type photoresist layer on both surfaces and then exposing and developing the photoresist layer. The upper resist layer 2000 and the lower resist layer 2001 are formed to cover the remaining portion of the upper insulating layer 1000 and the lower insulating layer 1001 in the following process.

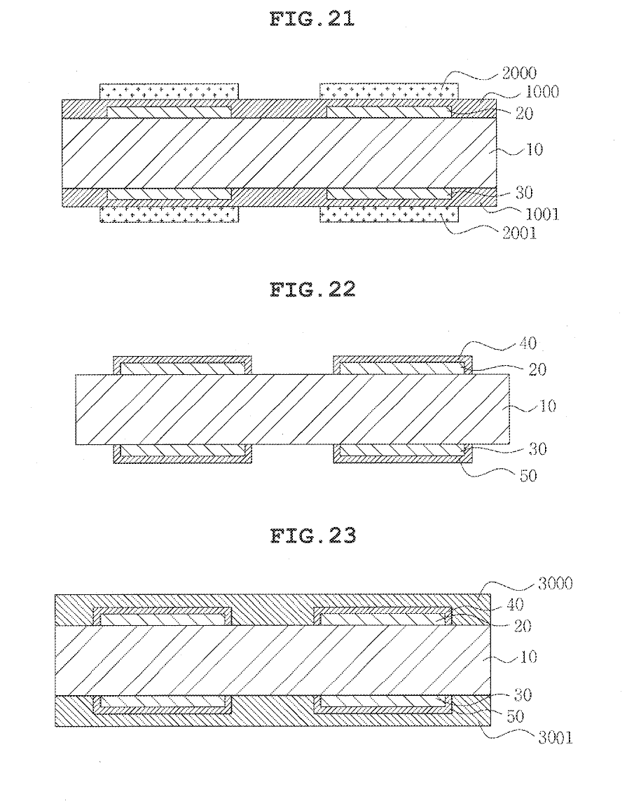

As illustrated in FIG. 22, the upper protective layer 40 and the lower protective layer 50 formed to enclose the side and the upper portion or the lower portion of the upper electrode 20 and the lower electrode 30 are formed by etching the upper insulating layer 1000 and the lower insulating layer 1001 depending on the patterns formed on the resist layers 2000 and 2001.

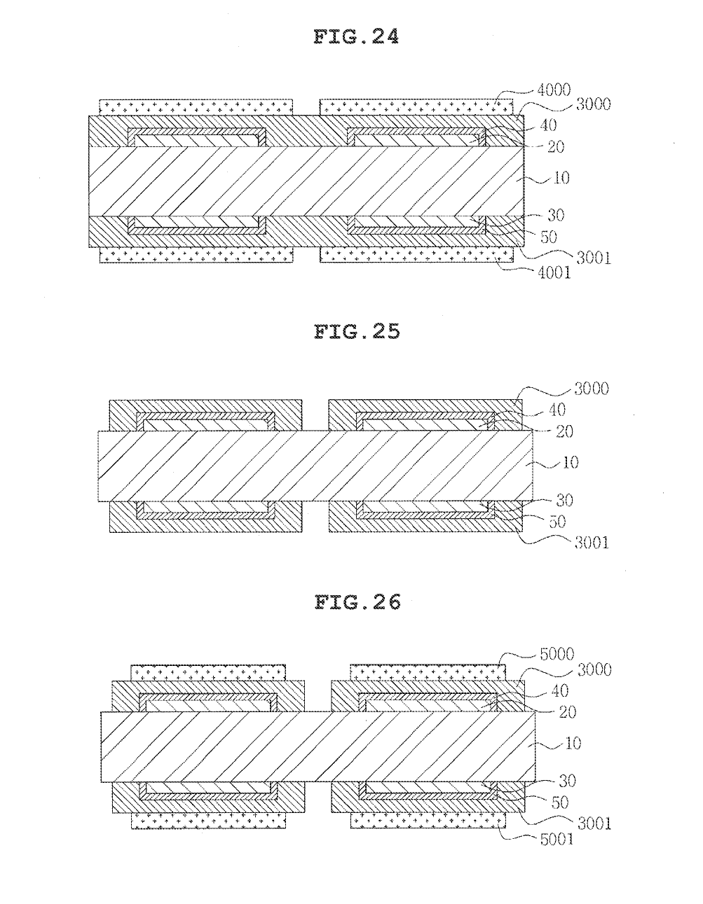

Further, as illustrated in FIG. 23, an upper metal mask 3000 and a lower metal mask 3001 made of chromium or gold are stacked on the quartz substrate 10, the positive type photoresist layer illustrated in FIG. 24 is applied, and then the photoresist layer is exposed and developed to form an upper resist layer 4000 and a lower resist layer 4001 having a predetermined shape.

Next, as illustrated in FIG. 25, the metal masks 3000 and 3001 are etched depending on the patterns formed on the resist layers 4000 and 4001 to enclose the side and the upper portion or the lower portion of the upper protective layer 40 and the lower protective layer 50.

Next, as illustrated in FIG. 26, an upper resist layer 5000 and a lower resist layer 5001 having a predetermined shape are formed by removing the resist layer stacked in FIG. 24, applying the positive type photoresist layer, and then exposing and developing the photoresist layer.

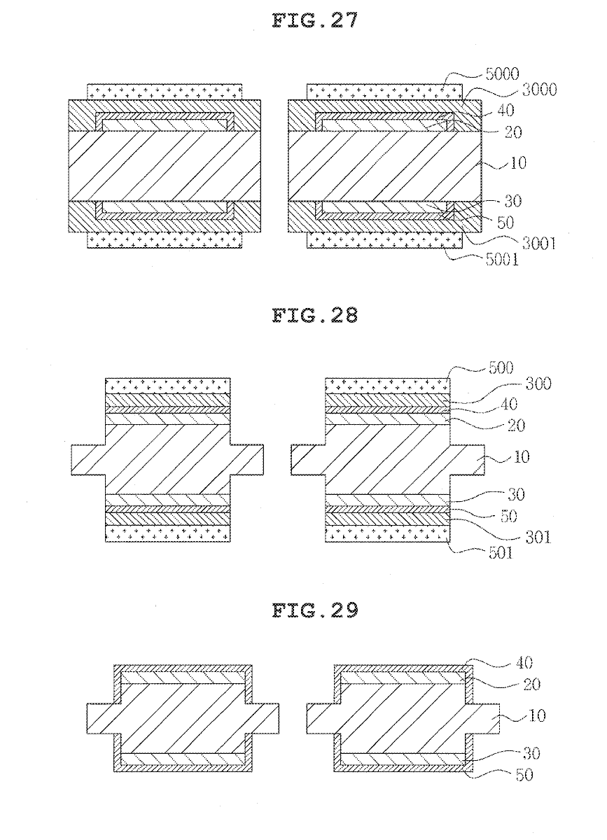

Further, as illustrated in FIG. 27, the substrate 10 is etched. The etching is performed by using, for example, the mixing solution of hydrofluoric acid and ammonium fluoride as the etching solution. By doing so, the appearance (shape when viewed in the Y′-axis direction) of the substrate 10 is formed.

Next, as illustrated in FIG. 28, the metal masks 3000 and 3001 are etched with a predetermined etching solution by using the resist layers 5000 and 5001 and then the AT cut quartz substrate 10 is half-etched up to the predetermined depth by using the above mixing solution as the etching solution. By doing so, the appearance of the exciting part 14 is formed.

Further, as illustrated in FIG. 29, after the resist layers 5000 and 5001 and the metal masks 3000 and 3001 are developed and removed, the upper protective layer 40 and the lower protective layer 50 are further formed at the electrodes 20 and 30 and the side of the exciting part.

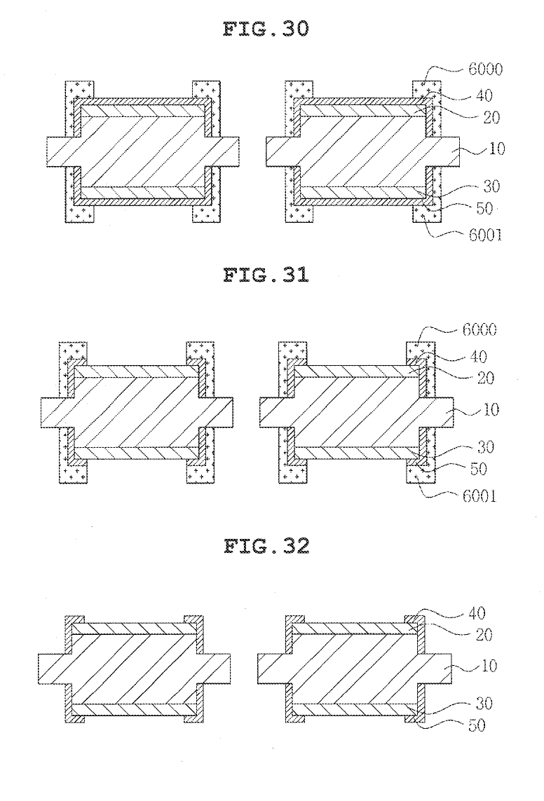

Next, as illustrated in FIG. 30, upper resist layers 6000 and 6001 having a predetermined shape are formed by applying the positive type photoresist layer and then exposing and developing the photoresist layer.

Further, as illustrated in FIG. 31, the upper protective layer 40 and the lower protective layer 50 are etched by the resist layers 6000 and 6001 to expose the trimming region. Next, as illustrated in FIG. 32, a product is completed by removing the resist layers 6000 and 6001.

According to another embodiment of the present invention as described above, the following effects may be obtained, in addition to the effects according to the embodiment of the present invention, as described above.

First, the upper protective layer 40 or the lower protective layer 50 serves as the existing shadow mask at the time of performing the trimming process to be able to radically remove the trimming region error occurring due to the mechanical processing such as the application of the existing shadow mask. Therefore, it is possible to very precisely control the trimming region.

Further, according to the embodiment of the present invention, at the time of performing the frequency trimming of the quartz vibrator, only the electrode region previously patterned is trimmed, such that the frequency may be easily controlled and the frequency scattering may be kept to be small.

Further, at the time of performing the trimming by the existing method, the defect of the drawing electrode occurs due to the step between the exciting part and the peripheral part while the trimming process is performed, but by using the improved method, it is little likely to cause the defect of the drawing electrode.

Since the protruding portion of the quartz substrate is different from the electrode structure, the manufacturing method according to the conventional art needs to further perform the separate electrode pattern process after the pattern of the protruding portion of the quartz substrate is completed, but according to an embodiment of the present invention, since the protruding structure of the quartz substrate is the same as the electrode structure, the metal mask for forming the protruding structure of the quartz substrate is used as the electrode as it is, and therefore there is no need to perform the separate electrode pattern process.

Further, according to the structure of the conventional art, the protruding portion and the electrode structure are formed with the electrode pattern through the step and thus it is highly likely to increase the disconnection risk at the time of forming the electrode in terms of the section characteristic, while according to the structure in accordance with an embodiment of the present invention, since the protruding structure is the same as the electrode, there is no risk of the electrode disconnection.

Further, according to an embodiment of the present invention, since the protruding portion of the quartz substrate is the same as the electrode structure, after the protruding portion of the quartz substrate is patterned, the metal mask is used as the electrode as it is, such that there is no need to perform the separate electrode pattern process. As a result, the manufacturing costs may be reduced by simplifying the process and reducing the frequency of the process of using gold which is a precious metal.

In addition, according to an embodiment of the present invention, it is possible to prevent the center mis-mismatching from occurring during the manufacturing process by making the shape of the protruding portion of the quartz substrate be the same as that of the electrode pattern.

Further, according to an embodiment of the present invention, since the protruding portion of the quartz vibrator and the electrode pattern have the same structure, it is possible to maximize the electrode area formed at the protruding portion of the quartz substrate and it is possible to secure the ESR improvement effect by increasing the electrode area.

Further, in the case of the structure according to the conventional art, since the appearance of the quartz substrate is formed and then the electrode pattern process is performed, the electrode process is performed in the state in which it is structurally very vulnerable to the impact, thereby causing the problem of the chip loss, the substrate damage, and the like, while according to an embodiment of the present invention, after the appearance of the quartz substrate is formed, there is no need to perform the separate electrode process, thereby minimizing the substrate damage, the chip loss, and the like.

Meanwhile, according to another embodiment of the present invention, it is possible to easily control the frequency and reduce the frequency scattering by precisely controlling the frequency trimming region of the quartz vibrator.

Further, according to an embodiment of the present invention, it is possible to effectively prevent the electrode located in the step region, and the like from short-circuiting during the frequency trimming.

Further, according to an embodiment of the present invention, it is possible to simplify the trimming process since there is no need to use the shadow mask, and the like when the trimming process is performed.

Further, according to an embodiment of the present invention, it is possible to improve the manufacturing competitiveness by improving the frequency scattering and the yield and simplifying the process.

Embodiments of the present invention may suitably comprise, consist or consist essentially of the elements disclosed and may be practiced in the absence of an element not disclosed. For example, it can be recognized by those skilled in the art that certain steps can be combined into a single step.

The terms and words used in the present specification and claims should not be interpreted as being limited to typical meanings or dictionary definitions, but should be interpreted as having meanings and concepts relevant to the technical scope of the present invention based on the rule according to which an inventor can appropriately define the concept of the term to describe the best method he or she knows for carrying out the invention.

As used herein, terms such as “first,” “second,” “one side,” “the other side” and the like are arbitrarily assigned and are merely intended to differentiate between two or more components of an apparatus. It is to be understood that the words “first,” “second,” “one side,” and “the other side” serve no other purpose and are not part of the name or description of the component, nor do they necessarily define a relative location or position of the component. Furthermore, it is to be understood that the mere use of the term “first” and “second” does not require that there be any “third” component, although that possibility is contemplated under the scope of the embodiments of the present invention.

The singular forms “a,” “an,” and “the” include plural referents, unless the context clearly dictates otherwise.

As used herein and in the appended claims, the words “comprise,” “has,” and “include” and all grammatical variations thereof are each intended to have an open, non-limiting meaning that does not exclude additional elements or steps.

Ranges may be expressed herein as from about one particular value, and/or to about another particular value. When such a range is expressed, it is to be understood that another embodiment is from the one particular value and/or to the other particular value, along with all combinations within said range.

Although the present invention has been described in detail, it should be understood that various changes, substitutions, and alterations can be made hereupon without departing from the principle and scope of the present invention. Accordingly, the scope of the present invention should be determined by the following claims and their appropriate legal equivalents.

What is claimed is:

1. A quartz vibrator, comprising:
a quartz substrate including an exciting part having a rectangular plate and a peripheral part having a thickness smaller than that of the exciting part and formed around the exciting part;
a first electrode formed on one surface of the quartz substrate and the whole surface of the exciting part; and
a second electrode formed on the other surface of the quartz substrate and the whole surface of the exciting part.

2. The quartz vibrator as set forth in claim 1, further comprising:
a first protective layer including an opening corresponding to a trimming region of the first electrode and formed on the first electrode.

3. The quartz vibrator as set forth in claim 1, further comprising:
a first pad formed on one surface of the quartz substrate; and
a first drawing electrode connecting the first pad to the first electrode,
wherein the exciting part protrudes in a shape corresponding to the first pad and the first drawing electrode, and the first pad and the first drawing electrode are formed at the corresponding shape portion of the exciting part.

4. The quartz vibrator as set forth in claim 3, wherein the exciting part formed with the first pad, the first drawing electrode, and the first electrode is a flat plane.

5. The quartz vibrator as set forth in claim 3, further comprising:
a first protective layer including an opening corresponding to a trimming region of the first electrode, formed on the first electrode, formed to include an opening corresponding to a connection portion formed on the first pad, and formed on a surface of the first drawing electrode.

6. The quartz vibrator as set forth in claim 5, wherein the first protective layer is formed on the first electrode and the first pad and a surface and a side of the first drawing electrode.

7. The quartz vibrator as set forth in claim 1, further comprising:
a second pad formed on the other surface of the quartz substrate; and
a second drawing electrode connecting the second pad to the second electrode,
wherein the exciting part protrudes in a shape corresponding to the second pad and the second drawing electrode, and the second pad and the second drawing electrode are formed at the corresponding shape portion of the exciting part.

8. The quartz vibrator as set forth in claim 7, wherein the second protective layer is formed on the second electrode and the second pad and a surface and a side of the second drawing electrode.

9. The quartz vibrator as set forth in claim 7, wherein the exciting part formed with the second pad, the second drawing electrode, and the second electrode is a flat plane.

10. The quartz vibrator as set forth in claim 7, further comprising:
a second protective layer including an opening corresponding to a trimming region of the second electrode, formed on the second electrode, formed to include an opening corresponding to a connection portion formed on the second pad, and formed on a surface of the second drawing electrode.

11. The quartz vibrator as set forth in claim 5, wherein the first electrode is provided with a depressed part corresponding to the opening of the first protective layer.

12. The quartz vibrator as set forth in claim 5, wherein the first protective layer is made of any one selected from a group consisting of aluminum oxide (Al₂O₃), aluminum nitride (AlN), aluminum oxynitride (AlON), silicon oxide (SiOx), silicon nitride (SiNx), silicon oxynitride (SiOxNy), silicon carbide (SiC), and titanium oxide (TiOx).

13. A method for manufacturing a quartz vibrator, comprising:
(A) forming a plurality of first and second electrodes on both surfaces of a reserved quartz substrate;
(B) dividing the reserved quartz substrate into the quartz substrate including one first electrode and second electrode by using a metal mask; and
(C) forming an exciting part protruding from a peripheral part of the quartz substrate and the first and second electrodes having the same shape as the exciting part by half-etching the first and second electrodes and the quartz substrate using a metal mask.

14. The method as set forth in claim 13, wherein the step (A) comprises:
(A-1) forming a first metal layer and a second metal layer on both surfaces of a reserved quartz substrate;
(A-2) forming a first resist layer on the first metal layer and forming a second resist layer on the second metal layer;
(A-3) patterning the first resist layer and the second resist layer as an electrode pattern; and
(A-4) forming the first and second electrodes by etching the first metal layer and the second metal layer using the first resist layer and the second resist layer.

15. The method as set forth in claim 13, wherein the step (B) comprises:
(B-1) forming a first metal mask on the first electrode of the quartz substrate and a second metal mask on the second electrode; and
(B-2) dividing the reserved quartz substrate into the quartz substrate including one first and second electrode by using the first and second metal masks and the first and second electrodes.

16. The method as set forth in claim 13, wherein the step (C) comprises:
(C-1) half-etching the first and second electrodes and the quartz substrate by using the first and second metal masks;
(C-2) forming the exciting part protruding from the peripheral part of the quartz substrate and the first and second electrodes having the same shape as the exciting part; and
(C-3) removing the first and second metal masks.

17. The method as set forth in claim 13, wherein, in the step (C), one surface of the quartz substrate is provided with a first pad and a first drawing electrode connecting the first pad to the first electrode and the exciting part is formed to protrude in a shape corresponding to the first pad and the first drawing electrode.

18. The method as set forth in claim 13, wherein, in the step (C), the other surface of the quartz substrate is provided with a second pad and a second drawing electrode connecting the second pad to the second electrode and the exciting part is formed to protrude in a shape corresponding to the second pad and the second drawing electrode.

19. The method as set forth in claim 13, further comprising:
after the step (A), (D) forming a first protective layer to enclose the first electrode and forming a second protective layer to enclose the second electrode; and
after the step (C), (E) exposing a trimming region of the first electrode by removing a central portion of the first protective layer and exposing a trimming region of the second electrode by removing a central portion of the second protective layer.

20. The method as set forth in claim 19, wherein the step (D) comprises:
(D-1) stacking a first insulating layer on the first electrode and stacking a second insulating layer on the second electrode; and
(D-2) forming the first protective layer to enclose the first electrode by patterning the first insulating layer and forming the second protective layer to enclose the second electrode by patterning the second insulating layer.

21. The method as set forth in claim 20, wherein, in the step (A), the first pad and the first drawing electrode connecting the first pad to the first electrode are further formed, and, in the step (D), the first protective layer is formed on the first drawing electrode.

22. The method as set forth in claim 20, wherein, in the step (A), the second pad and the second drawing electrode connecting the second pad to the second electrode are further formed, and, in the step (D), the second protective layer is formed on the second drawing electrode.
